(19) United States
(12) Patent Application Publication
(10) Pub. No.: US 2008/0105830 A1
(43) Pub. Date: May 8, 2008

(54) Gas Discharge Lamp, System and Method for the Hardening of Materials Hardenable by Uv Light as Well as Material Hardened by Uv Light

(76) Inventors: Heiko Runge, Munchen (DE); Udo Bastian, Morlenbach (DE); Karl-Heinz Meyer, Ortenberg (DE)

Correspondence Address: SCULLY SCOTT MURPHY & PRESSER, PC, 400 GARDEN CITY PLAZA, SUITE 300, GARDEN CITY, NY, 11530, US

(21) Appl. No.: 11/664,313

(22) PCT Filed: Sep. 30, 2005
(86) PCT No.: PCT/EP05/10609

§ 371 Date: Mar. 30, 2007

(30) Foreign Application Priority Data
Oct. 1, 2004 (DE) 1020040480052

(51) Int. Cl. H01J 37/32; H01J 17/32

(52) U.S. Cl. 250/432 R; 313/634

(57) ABSTRACT

The present invention relates to a gas discharge lamp for hardening materials hardenable by UV light comprising a tube (4) filled with filler gas (3) for generating a gas discharge for the emission of electromagnetic radiation to below 200 nm, with the employment of an inert gas facility for providing an inert gas and delivery of the inert gas to the surface of the material to be hardened.

Further, the present invention relates to a system and a method for hardening materials hardenable by UV light, and to a material hardened by the method in accordance with the invention.

The invention relates to a gas discharge lamp for the hardening of materials hardenable by UV light in accordance with claim 1, a system for the hardening of materials hardenable by UV light in accordance with claim 13, a method for the hardening of materials hardenable by UV light in accordance with claim 25 and a material hardened by UV light in accordance with claim 35.

In the most different fields there are put to use materials such as varnishes, coloured printing inks, casting masses, adhesives and the like. Originally and also in part still now solvent-containing and aqeous systems are employed. The heat energies used in the drying process are, however, very large and the partly highly volatile solvent component contributes to considerable environmental contamination or involves a need for great investment if, due to air purity regulations, solvent incineration facilities or solvent recovery facilities have to be installed.

An alternative to conventional solvent-containing systems consists in ultraviolet hardenable materials. Lately, UV hardening materials have largely established themselves in some fields, in other fields UV hardening is of increasing importance.

Thereby, for the hardening of UV-hardenable, in particular pigmented and thick layer materials, long-wave UV radiation of 320-380 nm as well as visible light between 380-450 nm is used for through-hardening, short-wave radiation between 200-320 nm for surface hardening and reduction of oxygen inhibition. The hardening of pigmented and thick layer systems is carried out preferably with photo-initiators which absorb in the visible region >400 nm. For these reasons, in the UV hardening of varnishes, coloured printing inks, adhesives and casting masses, primarily Hg medium pressure radiators are used, which in part emit specifically in the long-wave region (>400 nm).

Short-wave emitting radiators, e.g. excimer lasers with a wavelength of 172 nm, generate at the paint surface, for example in the case of clear varnishes, under inert conditions or in vacuum, a very thin through-hardened layer; the more deeply lying layers must, however, be after-hardened with a medium pressure radiator. Through this, a matt effect appears; the varnishes cannot, however, be completely through-hardened.

Low pressure radiators with a peak of 185 nm are used exclusively for ozone production and exclusively for photochemical purposes such as e.g. the splitting of water as well as the oxidation of organic components for cleaning air, water or substrate surfaces.

Disadvantageous with the methods described above, in particular with medium pressure radiators, is a high energy requirement of the radiators used, a high heat development of the radiators—which leads to a problem for, inter alia, temperature-sensitive substrates—as well as a great outlay in terms of construction and the need for cooling the radiators, with which there are associated high facility costs.

Furthermore, UV hardening is used predominantly for hardening 2-dimensional parts such as foils and plate goods. The hardening of 3-dimensional parts still presents greater problems and is carried out inter alia in air through the installation of complex UV facilities for the uniform hardening at all object points or under inert conditions.

It is therefore the object of the present invention to provide a system and a method which reduces the energy requirement and the constructional outlay, and minimises the heat delivery; furthermore lamp systems are to be provided which can be better matched to the structure of different 3-dimensional geometries.

The object is achieved in accordance with the invention by the gas discharge lamp characterized in claim 1.

In accordance with the present invention there is disclosed a gas discharge lamp for the hardening of materials hardenable by UV light comprising a tube (4) filled with filler gas (3) for generating a gas discharge for the emission of electromagnetic radiation to below 200 nm, with the employment of an inert gas facility for providing an inert gas and delivery of the inert gas to the surface of the material to be hardened.

Further, the object is achieved in accordance with the invention by the system characterized in claim 13.

In accordance with the present invention there is disclosed a system for the hardening of materials hardenable by UV light comprising a gas discharge for the emission of electromagnetic radiation to below 200 nm by means of a discharge in a tube filled with filler gas, and an inert gas facility for providing an inert gas and delivery of the inert gas to the surface of the material to be hardened.

The object is further achieved in accordance with the invention by the method characterized in claim 25.

In accordance with the present invention there is disclosed a method for the hardening of materials hardenable by UV light comprising the steps of emitting electromagnetic radiation to below 200 nm by means of a gas discharge lamp, providing an inert gas and delivering the inert gas to the surface of the material to be hardened.

Beyond this, the object is achieved in accordance with the invention by means of the material characterized in claim 35.

In accordance with the present invention there is disclosed a material hardened by UV light with the employment of a gas discharge lamp for emitting electromagnetic radiation to below 200 nm by means of a gas discharge in a tube filled with a filler gas, and with the employment of an inert gas facility for providing an inert gas and delivery of inert gas to the surface of the material to be hardened.

The gas discharge lamp is preferably a low pressure radiator.

The tube preferably has a diameter of 5 mm to 20 mm, preferably from 10 mm to 15 mm and particularly preferably from 12 mm to 13 mm.

In accordance with a preferred configuration the tube is of quartz glass which lets through wavelengths to below 200 nm, in particular to 185 nm.

Preferably the tube has a wall thickness between 0.5 mm and 2 mm, preferably between 0.8 mm and 1.5 mm and particularly preferably between 1 mm and 1.3 mm.

The filler gas is expediently of mercury and an Ne—Ar mixture in the ratio of Ne 0% to 100% and/or Ar 0% to 100%, preferably Ne 0% to 50% and Ar 50% to 100%, and particularly preferably Ne 20% to 30% and Ar 70% to 80%.

Advantageously, the filler gas has a gas pressure of from 0.5 mbar to 10 mbar, preferably from 0.5 mbar to 5 mbar and particularly preferably from 1 mbar to 3 mbar.

Preferably the gas discharge is generated by two electrodes situated in the tube and controlled by a ballast connected to the electrodes.

The ballast expediently regulates the discharge tube temperature to 85° C. to 150° C. by control of the current supply of the electrodes.

The gas discharge can also be generated by high-energy radiation, in particular radiation in the microwave range. The gas discharge may thereby, for example, be generated also in electrode-free radiator systems.

The gas discharge lamp may also be a medium pressure radiator.

Advantageously the inert gas is a chemically inert, gaseous compound, preferably argon, nitrogen or carbon dioxide.

The invention is explained in the following in more detail with reference to Figures. There is shown:

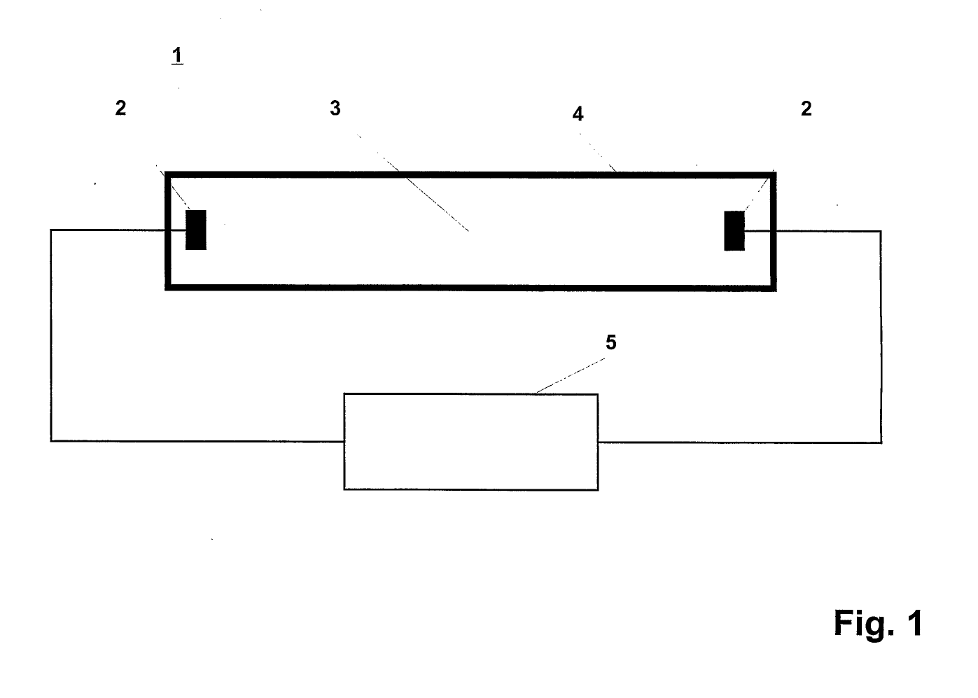

FIG. 1 a schematic representation of a gas discharge lamp, and

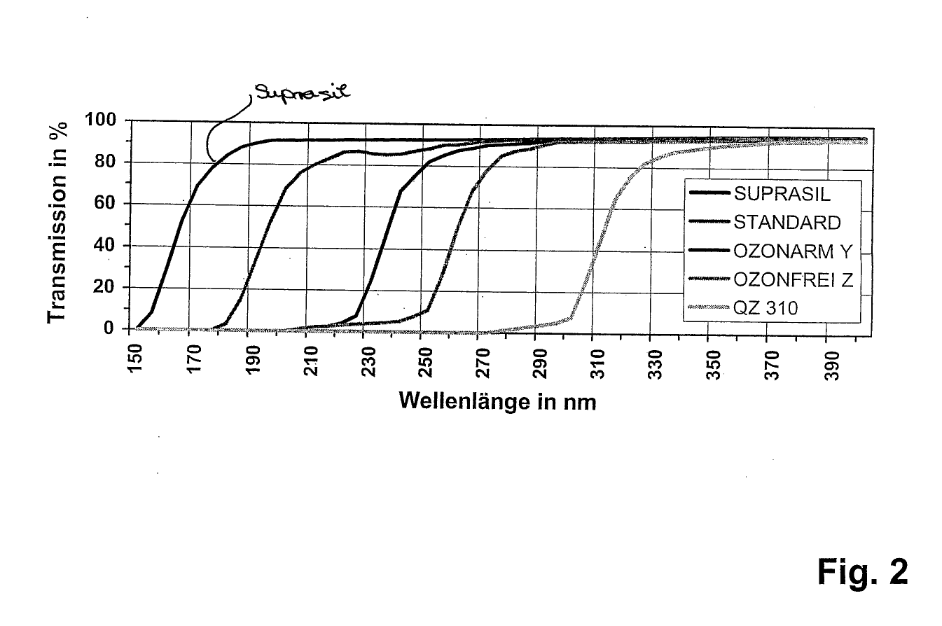

FIG. 2 the transmission of different quartz types.

FIG. 1 shows a schematic representation of a gas discharge lamp 1. The gas discharge lamp 1 consists of a vacuum-tight tube 4 with a filler gas 3 having a predetermined filler gas pressure, in which the gas discharge takes place, and mostly two metallic electrodes 2 which are melted into the tube 4. One electrode 2 delivers the electrons for the discharge, which are the delivered again to the external circuit via the second electrode 2. The emission of the electrons is mostly effected by means of thermionic emission (hot electrodes), but can however be brought about by emission in a strong electric field or directly by ion impact (ion induced secondary emission) (cold electrodes). Alongside these radiators which comprise electrodes, naturally also electrodeless radiation units 1 can be used, which are ignited by high-energy radiation such as e.g. microwaves.

The gas discharge lamp 1, for operation, has a ballast 5 which is connected to the electrodes and ignites the gas discharge in the gas discharge lamp 1 and provides a ballast for the operation of the lamp in an electrical circuit. Without a suitable current limitation of the gas discharge lamp 1 in an external electrical circuit the current in the gas discharge lamp 1 would rise so strongly through multiplication of the charge carriers in gas volumes of the tube 4 that it would rapidly come to destruction of the lamp.

Materials hardenable by UV light may be varnishes, coloured printing inks, adhesives, casting masses or the like.

There can be used for the gas discharge lamp 1 both low pressure radiators and medium pressure radiators. These are so optimized in accordance with the invention that the wavelength below 200 nm, in particular the wavelength 185 nm, is emitted with particularly high efficiency.

Also here it is a disadvantage of the medium pressure radiators that they produce a large amount of heat, what makes necessary an intensive cooling; through this, they cannot be—like e.g. low pressure radiators —brought into the chamber of a hardening facility filled with inert gas, since by the intensive ventilation the remainder O₂ concentration rises very rapidly to 20%; rather they must be externally attached to a hardening device. In turn this requires a very cost-intensive equipping of the hardening facility with quartz plates which are permeable for UV radiation with a wavelength of <200 nm (e.g. Suprasil). Further, the complete, externally mounted radiator unit must in addition be flooded with inert gas since otherwise ozone is formed and thus the short-wave UV radiation does not reach the substrate surface. Another possibility for hardening with Hg medium pressure radiation in inert gas atmosphere comprises carrying out the directing of the radiation with a cooling fluid, e.g. water. For this purpose, e.g. reflectors and/or housing are cooled with the cooling fluid. No turbulences arise in the irradiation chamber filled inert gas.

Mercury low pressure discharge lamps are radiation sources which generate radiation in their plasma discharge by the impact ionisation process with the mercury atoms. This radiation is spectrally distributed from ultraviolet to infrared. The most intensive radiation components lie, in clear contrast to medium pressure radiators, substantially at the wavelengths of 254 nm and 185 nm.

The smaller is the diameter of the tube 4 the higher is the 185 nm yield. Optimally, the tube 4 has a diameter of 5 mm to 20 mm, preferably from 10 mm to 15 mm and particularly preferably from 12 mm to 13 mm, whereby a diameter of 12 mm to 13 mm is optimal also from the production technical viewpoint.

The tube 4 has a wall thickness between 0.5 mm and 2 mm, preferably between 0.8 mm and 1.5 mm and particularly preferably between 1 mm and 1.3 mm.

The filler gas 3 of the low pressure radiators may be a mercury and Ar filling or a mercury and noble gas mixture such as Ar—Kr and Ar—Ne. The noble gas mixtures Ar—Kr and Ar—Ne exhibit a higher 185 nm yield than pure Ar filler. Here, there has proved to be optimal the noble gas mixture Ne—Ar with a proportion of Ne 0% to 100% and/or Ar 0% to 100%, preferably Ne 0% to 50% and Ar 50% to 100%, particularly preferably Ne 20% to 30% and Ar 70% to 80%. Furthermore, the 185 nm yield can be increased by a reduction of the gas pressure. The filler gas 3 has a gas pressure of 0.5 mbar to 10 mbar and preferably from 0.5 mbar to 5 mbar. Since, however, at values below 2 mbar gas pressure a reduction of the intensity of the 185 nm peak again arises, the optimal gas pressure of the filler gas 3 is at 2 mbar to 3 mbar.

By the use of different quartz materials for the tube 4 the emitted wavelength, and thus also the 185 nm yield, can be influenced. FIG. 2 shows the transmission of different quartz types for UV radiators. Thereby, the percent transmission is indicated graphically for different quartz types in dependence upon the wavelength in nanometres. As can be discerned from the graphic, only certain quartz types let through wavelengths of under 200 nm and in particular wavelengths of 185 nm. Transmissions at 185 nm are manifest inter alia by rock crystal and the synthetic quartz “Suprasil”. Further, the 185 nm yield is increased by the use of tubes 4 with a low wall thickness. The quartz glasses “Ilmasil hp” with a 1.3 mm wall thickness and “Hereaus Suprasil” with a 1 mm wall thickness have shown themselves to be optimal. Besides the mentioned quartz types on SiO₂ basis also ceramic or other inorganic materials can be used which have a transmission of UV radiation in the region of 100 nm to 200 nm.

The emission of the 185 nm line rises with increasing temperature of the radiator up to values around 150° C. Above this the emission reduces significantly, physically determined by the beginning self-absorption of the mercury resonance line. This being caused in that the radiator is not continuously heated up by a constant lamp current and therewith the radiation intensity passes through maxima, but instead the tube wall temperature can be kept constant at the desired value by regulation of the lamp current. With this, the intensity of radiation can be kept constant.

The gas discharge lamp 1 therefore has a ballast 5 which regulates the lamp current supply. Here, a particularly high 185 nm yield has been found in the range of 85° C. to 150° C. Above this, the 185 nm yield decreases again, whereby with a reduction of the filler pressure the broad maximum region reduces and the 185 nm yield again falls considerably more steeply at higher temperatures.

Depending on lamp current there arises a temperature of from 90° C. to 150° C. With the low lamp current of 500 mA there is applied e.g. in a radiator of the length 300 mm an electrical effective power of ca. 16 watts and at the current 1.2 A an electrical power of 33 watts. There is provided from this an efficiency of the radiation yield of 13.5% at 0.5 A and of 9% at 1.2 A. The optimal operating point at 1 A yields an efficiency of 150% in comparison with a conventional radiator of synthetic quartz. The determined powers of the 185 nm radiation are in the region between 2 and 3 watts.

The ballast 5 is adjustable in its current in a wide range, starting from a base value, by ±50%, i.e. for the low pressure radiator in accordance with the invention a range of 0.9 A±50% (0.45 A to 1.35 A). For other radiator kinds the corresponding base values are then adaptable by simple exchange of two chokes and a capacitor. The current setting in the ±50% range can be effected manually at a potentiometer or remotely controlled via a voltage interface. With the ballast 5 in accordance with the invention, this voltage interface is controlled via a comparator circuit which compares the tube wall temperature with a desired value temperature, or the current is set with fixed voltage values.

The tube 4 of the gas discharge lamp 1 may have the most varied geometries (meander-form, arc-form or coil form). An optimal exploitation of the generated radiation is provided with a cylindrical form. Although other geometries influence themselves mutually, in that they again themselves take up something of the generated radiation, the 185 nm yield is still high.

With the use of a medium pressure radiator as a gas discharge lamp the tube 4 optimally has a length of 10 to 3000 mm and a tube diameter of ca. 16 to 28 mm. The discharge tube temperature is approximately between 700° C. and 900° C. As material for the tube 4 a quartz glass is taken again which lets through wavelengths of under 200 nm in particular of 185 nm.

In order to suppress the ozone formation generated by UV radiation under oxygen, as well as the effect of oxygen inhibition with radical hardening varnishes, coloured printing inks, adhesives and casting masses, the hardening process takes place under an inert gas (protective gas). An inert gas facility serves here for the provision of the inert gas and delivery of the inert gas to the surface of the material to be hardened. Any chemically inert gaseous compounds can be used as inert gases, such as e.g. noble gases like helium or argon; however, also e.g. nitrogen or carbon dioxide can be put to use as inert gas. Carbon dioxide can e.g. be used in the form of dry ice or in gaseous form. For obtaining unimpeachable coating characteristics one works in the inerting process with a remainder O₂ concentration between 0.0001 and 10%, preferably between 0.3 and 3%.

Uv hardenable materials consist in substance of photo-initiators, prepolymers (pre-cross-linked basic constituents), monomers (basic constituents usable as reactive thinners), additives, fillers and/or pigments.

Through the action of UV radiation, free radicals are formed from the photo-initiators contained in these materials, which trigger a cross-linking of the system and harden it in shortest time.

As radiation hardenable compounds there come into consideration e.g (meth)acrylate compounds, vinylether, vinylamide, nonsaturated polyesters e.g. based on malic acid or formalic acid if applicable with styrene as a reactive thinner or maleinimide/vinylether systems.

(Meth)acrylate compounds such as polyester(meth)acrylate, polyether(meth)acrylate, urethane(meth)acrylate, epoxy(meth)acrylate, silicone(meth)acrylate, acrylated polyacrylate, are preferred.

Preferably at least 40 Mol %, particularly preferably at least 60%, of the radiation hardenable ethylenic nonsaturated groups are (meth)acrylate groups.

The radiation hardenable compounds may contain further reactive groups for an additional thermal hardening, e.g melamine, isocyanate, epoxide, anhydride, alcohol, carbonic acid groups, e.g. by a chemical reaction of alcohol, carbonic acid, amine, epoxide, anhydride, isocyanate or melamine groups (dual cure).

The radiation hardenable compounds can be put to use e.g. as solution e.g. in an organic solvent or water, as aqueous dispersion or emulsion, as powder or as liquid 100% material.

Preferably the radiation hardenable compounds and therefore also the radiation hardenable masses are flowable at room temperature. The radiation hardenable masses contain preferably less than 20 weight %, in particularly less than 10 weight %, organic solvent and/or water. They are preferably solvent-free and water-free (100% solid substance).

The radiation hardenable masses may contain, besides the radiation hardenable compounds, further components as binder. There come into consideration pigments, rheological agents, colouring agents, stabilisors, etc.

For hardening with UV light customary photo-initiators are in general used.

As photo-initiators there come into consideration e.g. benzophenones, alkylbenzophenones, hologenmethylated benzophenones, Michler's ketone, e.g., anthrone and halogenated benzophenones. Further common photo-initiators are α-hydroxyketones, α-amino ketones, thioxanthones and methylbenzoylformate (MBF). Benzoine and its derivatives are also suitable. Similarly effective photo-initiators are anthrachinone and many of its derivatives, for example β-methylanthrachinone, tert.-butylanthrachinone and anthrachinone carbonic acid ester and, particularly effective, photo-initiators with an acylphosphine oxide group such as acylphosphine oxide or bisacylphosphine oxide, e.g. 2,4,6-trimethylbenzoldiphenylphosphine oxide (Lucirin® TPO).

It is an advantage of the invention that the content of the photo-initiators in the radiation hardenable mass can be significantly reduced.

The radiation hardenable masses preferably contain less than 10 weight parts, in particular less than 4 weight parts, particularly preferably less than 1.5 weight parts, photo-initiator for 100 weight parts radiation hardenable compounds.

In particular a quantity of 0.01 weight parts to 1.5 weight parts, in particular 0.01 to 1 weight part photo-initiator is sufficient.

The proposed gas discharge lamp 1 in connection with the inert gas facility is suitable both for the hardening of radical and cationic varnishes, coloured printing inks, adhesives or casting masses. Here, both clear varnishes and also pigmented systems can be hardened in the colours e.g. white, cyan, magenta, yellow or black as well as mixtures of these. With pigmented varnishes, coloured printing inks, adhesives or casting masses, with this method layer thicknesses up to >40 μm can be hardened. Clear varnishes or filled systems can likewise be hardened without problems up to layer thicknesses >>2000 μm. It has turned out that also varnish systems which contains UV absorbers for increasing UV and weather resistance, in layer thicknesses of >100 μm as well as highly pigmented white systems, e.g. with titanium dioxide as pigment, can be hardened without problems.

The distance of the gas discharge lamp 1 from the substrate surface can in this method be between 1 cm and >18 cm. For the hardening of varnishes, coloured printing inks, adhesives and casting masses there can be employed one or more radiators or a radiator array. Through the low heat emission of the radiators the coated and hardened substrate heats up only insignificantly, aside from the heat of reaction.

A further application also lies in the pre-treatment of substrates for the improvement of substrate adhesion; here, the surface of the substrate is irradiated under inert conditions with one or several radiator units 1 and “activated”, which has the consequence of an increase of the surface tension of the substrate. The radicals thereby formed radical can now react e.g. with the non-saturated groups of the varnishes, coloured printing inks, adhesives or casting masses and generate a chemical bond between substrate and coating; with one or several further radiator units 1 the coating material can then be hardened under inert conditions. Through this a significant improvement of adhesion of the varnishes, coloured printing inks, adhesives or casting masses can be obtained on various substrates. In a further method the substrate, pre-treated with one or more UV radiator units 1 under inert conditions, can be pre-treated with a photo-active “UV primer”; a chemical bond arises between substrate and primer; by means of a further UV irradiation step with one or more radiator unit(s) 1 under inert conditions this effect can be improved further. After subsequent coating with UV hardenable coating materials and renewed UV hardening under inert conditions with one or more UV units 1 there is now generated a chemical bond between primer and coating material. By this process the adhesion of UV-cross-linkable systems to various substrates can be significantly improved. With both mentioned methods, for increasing the surface tension and the improvement of the substrate adhesion, after the pre-treatment step with radiator unit(s) 1 under inert conditions, the UV hardening can be executed in the subsequent primer and coating steps also with conventional medium pressure radiators in air.

Another application of the radiator unit 1 is the field of making germ-free, sterilization and/or disinfection of substrate surfaces.

Another application of the radiator unit 1 is the production of matt and dull matt surfaces.

An advantage of the system and method in accordance with the invention lies in the low temperature development in the UV hardening, since also little energy is applied by the low pressure radiator. This is particularly significant in the coating of temperature-sensitive substrates such as plastics, paper, wood etc. Further, low pressure radiators have a considerably lower energy requirement in comparison with medium pressure radiators, which results in reduced energy costs. Moreover, with the gas discharge lamps in accordance with the invention every possible geometry can be followed; that is, the lamp may be meander or U-shaped, through which in the case of objects having a curved surface the radiator can be adapted optimally to the surface for hardening. Furthermore, the hardening of clear varnishes and pigmented systems is possible in considerably shorter time. Also the hardening of thick layers can be effected with the gas discharge lamp under inert gas in accordance with the invention. Through the low temperature development with low pressure radiators the requirement for a cooling of the radiator is absent, through which the constructional outlay is reduced and the handling of the radiator is simplified, since for example a radiator change is possible without waiting time until cooling takes place. Through the reduced constructional outlay the equipment costs are also reduced. Further, pre-treatment of substrates is also possible. Furthermore the radiator can still be used for sterilization and disinfection, and the hardening of radical and cationic hardening systems as well as of UV stabilized varnishes is possible also. Likewise, the adhesion of UV permeable substrates (cationic and radical) and non-transparent substrates with cationic adhesives is possible. A further application is the matting and through-hardening of pigmented systems.

The method can carried out under inert conditions in station-wise or continuous operation for example for the refinement of web materials such as paper, foils or plate goods for printing, coating and lining/laminating of two and three-dimensional bodies as well as also for the refining of 3-dimensional bodies.

### EXAMPLES

All tests, if not otherwise indicated, were carried out with 2 optimized UV low pressure radiators with an amplified emission in the range of 185 nm. Normal amalgam radiators (conventional quartz) do not exhibit any emission in the short-wave UV area at 185 nm but only at 254 nm.

Amalgam radiators made of synthetic quartz exhibit emissions at 254 nm and 185 nm; the emission at 185 nm is, however, considerably lower than with the optimized radiators.

1. Hardening of a UV Clear Varnish

A UV solvent-containing clear varnish of the company DuPont Performance Coatings was applied to a glass plate (SD ca. 40 μm, FK=50%), the solvent evaporated, and then brought into a ‘UVACube inert’. It was hardened by with 2 low pressure radiators at a distance from the radiator of ca. 6 cm (remainder O₂ concentration=1.5%). After 1 s exposure time the material is hardened completely as a high gloss, scratch-resistant film. In the KmnO₄ test against white paper no colouring of the film is to be recognized.

2. Hardening of a UV Clear Varnish

A clear varnish consisting of 50 g Laromer® PO 84 F (BASF), 1.5 g TMPTA (BASF) and 1 g Darocur® MBF (Ciba SC) as a photo-initiator was applied on a glass plate (SD ca. 40 μm) and brought into a ‘UVACube inert’. It was hardened with 2 radiators at a distance from the radiators of ca. 6 cm (remainder O₂ concentration=1.5%). After 2 s exposure time the material is hardened completely as a high gloss, scratch-resistant film. In the KMnO₄ test against white paper a minimal colouring of the film is to be recognized.

3. Hardening of a UV Clear Varnish as a Casting Mass

The same varnish is filled into an aluminium lid (SD ca. 3 mm). The material was then exposed for 60 s in the ‘UVACube inert’ at a spacing from the radiator of ca. 18 cm with 2 low pressure radiators (rest O₂ concentration=1.4%). The mass is hardened completely, the surface scratch-resistant; a soft, ca. 3 mm thick polymer has formed.

4. Hardening of a UV Clear Varnish (MBF) Containing UV Absorbers

A clear varnish consisting of 100 g Laromer® PO 84 F (BASF), 5.0 g Tinuvin® 1130 (Ciba SC) as UV absorber and 2.0 g Darocur® MBF (Ciba SC) as a photo-initiator was applied to white card (SD ca. 12 μm) and brought into a ‘UVACube inert’. It was hardened with 2 radiators at a spacing from the radiator of ca. 6 cm (remainder O₂ concentration=1.4%). After 2 s exposure time the material is hardened completely as a high gloss, scratch-resistant film. In the KMnO₄ test against white paper a minimal colouring of the film is to be recognized.

5. Hardening of a UV Clear Varnish Containing UV Absorber in Thick Layer (MBF)

The same varnish is applied with a layer thickness of ca. 40 μm on a white card. The material was then exposed for 30 s in the ‘UVACube inert’ at a spacing from the radiator of ca. 6 cm with 2 low pressure radiators (remainder O₂ concentration=1.4%). The film is hardened completely, the high gloss surface is absolutely scratch-resistant. After an exposure time of 10 s the film has not yet hardened completely.

6. Hardening of a UV Clear Varnish Containing UV Absorber in Thick Layer (MBF)

With the same varnish a layer thickness of ca. 100 μm was applied onto white card. The material was then exposed the ‘UVACube inert’ for 60 s at a distance from the radiator of ca. 6 cm with 2 low pressure radiators (reminder O₂ concentration=1.4%). The film is hardened completely, the high gloss surface is absolutely scratch-resistant.

7. Hardening of a UV Clear Varnish Containing UV Absorber (TPO)

A clear varnish consisting of 100 g Laromer® PO 84 F (BASF), 5.0 g Tinuvin® 1130 (Ciba SC) as UV absorber and 2.0 g Lucirin® TPO-L (BASF) as photo-initiator was applied on a white card (SD ca. 40) and brought into a ‘UVACube inert’. It was hardened with 2 radiators at a spacing from the radiator of ca. 6 cm (remainder O₂ concentration=1.4%). After 5 s exposure time the material is hardened completely as a high gloss, scratch-resistant film. In the KMnO₄ test against white paper a minimal colouring of the film is to be recognized.

8. Hardening of a UV Clear Varnish Containing UV Absorber in Thick Layer (TPO)

The same varnish is applied in a layer thickness of ca. 100 μm on a white card. The material was then exposed for 5 s in the ‘UVACube inert’ at a spacing of ca. 6 cm from the radiator with 2 low pressure beams (remainder O₂ concentration 1,4%). The film is hardened completely, the high gloss surface is absolutely scratch-resistant.

9. Hardening of a Radical Hardening UV Ink Jet Colour White

A white, highly pigmented ink jet colour was applied in an SD of 12 μm on white card and brought into a ‘UVACube inert’. Exposure then took place at a distance to the radiator of ca. 6 cm for<2 s with 2 radiators (remainder O₂ concentration=1.4%). The material is hardened completely and manifests a gloss surface.

If one carries out the UV hardening under the same conditions with amalgam radiators (normal quartz), the material is not yet hardened after an exposure time of 90 s.

If one carries out the UV hardening under the same conditions with a “normal” UV low pressure radiator of synthetic quartz, the material is hardened only after 10 s and has a matt surface.

Here there is clearly manifest the effect of the radiator with the increased emission at 185 nm.

10. Hardening of a Radical Hardening UV Ink Jet Colour White

A white, highly pigmented ink jet colour was applied in an SD of 40 μm on white card and brought into a ‘UVACube inert’. Exposure then took place at a distance to the radiator of 18 cm for 60 s with 2 radiators (remainder O₂ concentration=1.4%). The material is hardened completely and manifests a structured surface.

11. Hardening of a Radical Hardening UV Ink Jet Colour Yellow

A yellow, highly pigmented ink jet colour was applied in an SD of 12 μm on white card and brought into a ‘UVACube inert’. Exposure then took place at a distance to the radiator of ca. 6 cm for <<2 s with 2 radiators (remainder O₂ concentration=1.4%). The material is hardened completely and manifests a gloss surface.

If one carries out the UV hardening under the same conditions with amalgam radiators (normal quartz), the material is only hardened after an exposure time of 90 s and manifests a structured surface.

If one carries out the UV hardening under the same conditions with a “normal” UV low pressure radiator of synthetic quartz, the material is hardened only after 10 s and manifests a matt surface has.

Here there is clearly manifest the effect of the radiator with the increased emission at 185 nm.

12. Hardening of a Radical Hardening UV Ink Jet Colour Yellow

A yellow, highly pigmented ink jet colour was applied in an SD of 40 μm on white card and brought into a ‘UVACube inert’. Exposure then took place at a distance to the radiator of ca. 6 cm for 20 s with 2 radiators (remainder O₂ concentration=1.4%). The material is hardened completely and manifests a structured surface.

13. Hardening of a Radical Hardening UV Ink Jet Colour Cyan

A cyan coloured, highly pigmented ink jet colour was applied in an SD of 12 μm on white card and brought into a ‘UVACube inert’. Exposure then took place at a distance to the radiator of ca. 6 cm for 2 s with 2 radiators (remainder O₂ concentration=1.4%). The material is hardened completely and manifests a gloss surface.

If one carries out the UV hardening under the same conditions with amalgam radiators (normal quartz), the material is only hardened after an exposure time of 90 s and manifests a gloss surface.

If one carries out the UV hardening under the same conditions with a “normal” UV low pressure radiator of synthetic quartz, the material is hardened only after 5 s and manifests a matt surface has.

Here there is clearly manifest the effect of the radiator with the increased emission at 185 nm.

14. Hardening of a Radical Hardening UV Ink Jet Colour Magenta

A magenta coloured, highly pigmented ink jet colour was applied in an SD of 12 μm on white card and brought into a ‘UVACube inert’. Exposure then took place at a distance to the radiator of ca. 6 cm for <2 s with 2 radiators (remainder O₂ concentration=1.4%). The material is hardened completely and manifests a gloss surface.

If one carries out the UV hardening under the same conditions with amalgam radiators (normal quartz), the material is only hardened after an exposure time of 90 s and manifests a gloss surface.

If one carries out the UV hardening under the same conditions with a “normal” UV low pressure radiator of synthetic quartz, the material is hardened only after 5 s and has a slightly matted surface has. Here there is clearly manifest the effect of the radiator with the increased emission at 185 nm.

15. Hardening of a Radical Hardening UV Ink Jet Colour Black

A black, highly pigmented ink jet colour was applied in an SD of 12 μm on white card and brought into a ‘UVACube inert’. Exposure then took place at a distance to the radiator of ca. 6 cm for 5 s with 2 radiators (remainder O₂ concentration=1.4%). The material is hardened completely and manifests a matt surface.

If one carries out the UV hardening under the same conditions with amalgam radiators (normal quartz), the material is only hardened after an exposure time of 90 s and manifests a matt surface.

If one carries out the UV hardening under the same conditions with a “normal” UV low pressure radiator of synthetic quartz, the material is hardened only after 10 s and manifests a matt surface.

Here there is clearly manifest the effect of the radiator with the increased emission at 185 nm.

16. Hardening of a Cationic Hardening UV ‘Flexofarbe’ White

A white, highly pigmented ‘Flexofarbe’ was applied in an SD of 12 μm on white card and brought into a ‘UVACube inert’. Exposure then took place at a distance to the radiator of ca. 6 cm for 20 s with 2 radiators (remainder O₂ concentration=1.4%). The material is hardened completely and manifests a matt surface.

If one carries our the same test in an SD of 6 μm, the material is hardened completely after 10 s and manifests a gloss surface.

17. Hardening of a Cationic Hardening UV ‘Flexofarbe’ Yellow

A yellow, highly pigmented ‘Flexofarbe’ was applied in an SD of 12 μm on white card and brought into a ‘UVACube inert’. Exposure then took place at a distance to the radiator of ca. 6 cm for 20 s with 2 radiators (remainder O₂ concentration=1.4%). The material is hardened completely and manifests a gloss surface.

If one carries our the same test in an SD of 6 μm, the material is hardened completely after 10 s and manifests a gloss surface.

18. Hardening of a Cationic Hardening UV ‘Flexofarbe’ Cyan

A cyan coloured, highly pigmented ‘Flexofarbe’ was applied in an SD of 12 μm on white card and brought into a ‘UVACube inert’. Exposure then took place at a distance to the radiator of ca. 6 cm for 30 s with 2 radiators (remainder O₂ concentration=1.4%). The material is hardened completely and manifests a matt surface.

If one carries our the same test in an SD of 6 μm, the material is hardened completely after 10 s and manifests a matt surface.

19. Hardening of a Cationic Hardening UV ‘Flexofarbe’ Magenta

A magenta coloured, highly pigmented ‘Flexofarbe’ was applied in an SD of 12 μm on white card and brought into a ‘UVACube inert’. Exposure then took place at a distance to the radiator of ca. 6 cm for 20 s with 2 radiators (remainder O₂ concentration=1.4%). The material is hardened completely and manifests a gloss surface.

If one carries our the same test in an SD of 6 μm, the material is hardened completely after 10 s and manifests a gloss surface.

20. Hardening of a Cationic Hardening UV ‘Flexofarbe’ Black

A black, highly pigmented ‘Flexofarbe’ was applied in an SD of 12 μm on white card and brought into a ‘UVACube inert’. Exposure then took place at a distance to the radiator of ca. 6 cm for 30 s with 2 radiators (remainder O₂ concentration=1.4%). The material is not hardened completely and manifests a dull matt surface.

If one carries our the same test in an SD of 60 μm, the material is hardened completely after 10 s and manifests a dull matt surface.

21. Production of Matt Surfaces with Cationic Hardening UV ‘Flexofarbe's

If one exposes the cationic hardening ‘Flexofarbe's in an SD of ca. 12 μm for only 10 s, then one obtains “dull matted” surfaces, whilst the deeper layers are not yet hardened. By means of a further irradiation with low pressure radiators or also conventional Hg medium pressure radiators one can fix this surface structure and generate matt surfaces.

22. Pre-treatment of Plastic Surfaces for the Improvement of the Adhesion of Varnishes, Coloured Printing Inks, Adhesives or Casting Masses

A conventional PMMA plate is exposed for ca. 10 s at a distance of ca. 6 cm to the radiator with 2 optimized low pressure radiators. Thereby, the surface tension of the plastic of ca. 38 Nm/m changes to ca. 46 Nm/m. After ca. 20 s irradiation, surface tension values>50 Nm/m are achieved.

If one applies an e.g. radical hardening UV varnish to the surface so treated, it manifests a good adhesion to the substrate whilst an adhesion to the untreated PMMA does not arise.

By applying a primer or UV primer to the pre-treated surface and subsequent application and hardening of an e.g. radical hardening UV varnish (there can if applicable be effected, after the application of primer, an additional UV irradiation) the adhesion to the PMMA can be again improved significantly.

Analogous results were achieved also on plastics such as PE, PP, Pa, Teflon and also on silicone paper.

1. Gas discharge lamp for hardening materials hardenable by UV light comprising a tube (4) filled with filler gas (3) for generating a gas discharge for the emission of electromagnetic radiation to below 200 nm, with the employment of an inert gas facility for providing an inert gas and delivery of the inert gas to the surface of the material to be hardened, and wherein the tube (4) is constituted of quartz glass, which allows for a passage of wavelengths as far as below 200 nm and particularly as low as 185 nm.

2. Gas discharge lamp according to claim 1, wherein the gas discharge lamp (1) is a low pressure radiator.

3. Gas discharge lamp according to claim 1, wherein the tube (4) has a diameter of 5 mm to 20 mm, preferably from 10 mm to 15 mm and particularly preferably from 12 mm to 13 mm.

4. (canceled)

5. Gas discharge lamp according to claim 1, wherein the tube (4) has a wall thickness of between about 0.5 mm and 2 mm, preferably between 0.8 mm and 1.5 mm, and particularly preferably between 1 mm and 1.3 mm.

6. Gas discharge lamp according to claim 1, wherein the filler gas (3) is of mercury and an Ne—Ar mixture in the ratio Ne 0% to 100% and/or Ar 0% to 100%, preferably Ne 0% to 50% and Ar 50% to 100% and particularly preferably Ne 20% to 30% and Ar 70-080%.

7. Gas discharge lamp according to claim 1, wherein the filler gas (3) has a gas pressure of 0.5 mbar to 10 mbar, preferably from 0.5 mbar to 5 mbar and particularly preferably from 1 mbar to 3 mbar.

8. Gas discharge lamp according to claim 1, wherein the gas discharge is generated by two electrodes (2) situated in the tube (4) and controlled by a ballast (5) connected to the electrodes (2).

9. Gas discharge lamp according to claim 8, wherein by control of the power supply of the electrodes (2) the ballast (5) regulates the discharge tube temperature to between about 85° C. to 150°0 C.

10. Gas discharge lamp according to claim 1, wherein the gas discharge is generated electrode-free by high-energy radiation, such as radiation in the microwave range.

11. Gas discharge lamp according to claim 1, wherein the gas discharge lamp (1) is a medium pressure radiator.

12. Gas discharge lamp according to claim 1, wherein the inert gas is a chemically inert gaseous compound, selected from the group consisting of argon, nitrogen or carbon dioxide.

13. System for hardening materials hardenable by UV light, comprising a gas discharge lamp for the emission of electromagnetic radiation to below 200 nM by means of a gas discharge in a tube (4) filled with filler gas (3), and
an inert gas facility for providing an inert gas and delivery of the inert gas to the surface of the material to be hardened, and wherein the tube (4) is constituted of quartz glass, which allows for a passage of wavelengths as far as below 200 nm and particularly as low as 185 nm.

14. System according to claim 13, wherein the gas discharge lamp (1) is a low pressure radiator.

15. System according to claim 13, wherein the tube (4) has a diameter of 5 mm to 20 mm, preferably from 10 mm to 15 mm and particularly preferably from 12 mm to 13 mm.

16. (canceled)

17. System according to claim 13, wherein the tube (4) has a wall thickness between about 0.5 mm and 215 mm, preferably between 0.8 mm and 1.5 mm, and particularly preferably between 1 mm and 1.3 mm.

18. System according to claim 13, wherein the filler gas (3) is of mercury and an Ne—Ar mixture in the ratio Ne 0% to 100% and/or Ar 0% to 100%, preferably Ne 0% to 50% and Ar 50% to 100% and particularly preferably Ne 20% to 30% and Ar 70% to 80%.

19. System according to claim 13, wherein the filler gas (3) has a gas pressure of about 0.5 mbar to 10 mbar, preferably from 0.5 mbar to 5 mbar and particularly preferably from 1 mbar to 3 mbar.

20. System according to claim 13, wherein the gas discharge is generated by two electrodes (2) situated in the tube (4) and controlled by a ballast (5) which is connected to the electrodes (2).

21. System according to claim 20, wherein a control of the power supply of the electrodes (2) the ballast (5) regulates the discharge tube temperature to about 85° C. to 150° C.

22. System according to claim 13, wherein the gas discharge is generated electrode-free by high-energy radiation, in particular radiation in the microwave range.

23. System according to claim 13, wherein the gas discharge lamp (1) is a medium pressure radiator.

24. System according to claim 13, wherein the inert gas is a chemically inert gaseous compound, selected from the group consisting of argon, nitrogen or carbon dioxide.

25. Method for hardening materials hardenable by UV light, comprising the steps of:
emitting electromagnetic radiation to below 200 nm by means of a gas discharge lamp (1),
providing an inert gas, and
delivering of the inert gas to the surface of the material to be hardened, and wherein there is provided a tube (4) constituted of quartz glass, which allows for a passage of wavelengths as far as below 200 nm and particularly as low as 185 nm.

26. Method according to claim 25, wherein the tube (4) has a diameter of 5 mm to 20 mm, preferably from 10 mm to 15 mm and particularly preferably from 12 mm to 13 mm.

27. (canceled)

28. Method according to claim 26, wherein the tube (4) has a wall thickness between 0.5 mm and 2 mm, preferably between 0.8 mm and 1.5 mm, and particularly preferably between 1 mm and 1.3 mm.

29. Method according to claim 25, wherein there is provided a filler gas of mercury and an Ne—Ar mixture in the ratio Ne 0% to 100% and/or Ar 0% to 100%, preferably Ne 0% to 50% and Ar 50% to 100% and particularly preferably Ne 20% to 30% and Ar 70% to 80%.

30. Method according to claim 25, wherein there is provided a gas pressure of 0.5 mbar to 10 mbar, preferably from 0.5 mbar to 5 mbar and particularly preferably from 1 mbar to 3 mbar.

31. Method according to claim 25, wherein there is implemented a generation of the gas discharge by two electrodes (2) situated in the tube (4) and control by a ballast (5) connected to the electrodes (2).

32. Method according to claim 31, wherein there is a regulation of the discharge tube temperature to about 85° C. to 150° C. by means of the ballast (5) through control of the power supply of the electrodes (2).

33. Method according to claim 25, wherein there is effected a generation of the gas discharge electrode-free by high-energy radiation, in particular radiation in the microwave range.

34. Method according to claim 25, wherein the inert gas is a chemically inert gaseous compound, selected from the group consisting of argon, nitrogen or carbon dioxide.

35. Materials hardenable by UV light with the employment of a gas discharge lamp (1) for the emission of electromagnetic radiation to below 200 nm by means of a gas discharge in a tube (4) filled with filler gas (3), and
an inert gas facility for providing an inert gas and delivery of the inert gas to the surface of the material to be hardened, and wherein the tube (4) is constituted of quartz glass, which allows for a passage of wavelengths as far as below 200 nm and particularly as low as 185 nm.

36. Material according to claim 35, wherein the gas discharge lamp (1) is a low pressure radiator.

37. Material according to claim 35, wherein the tube (4) has a diameter of 5 mm to 20 mm, preferably from 10 mm to 15 mm and particularly preferably from 12 mm to 13 mm.

38. (canceled)

39. Material according to claim 35, wherein the tube (4) has a wall thickness of between 0.5 mm and 2 mm, preferably between 0.8 mm and 1.5 mm, and particularly preferably between 1 mm and 1.3 mm.

40. Material according to claim 35, wherein the filler gas is of mercury and an Ne—Ar mixture in the ratio Ne 0% to 100% and/or Ar 0% to 100%, preferably Ne 0% to 50% and Ar 50% to 100% and particularly preferably Ne 20% to 30% and Ar 70% to 80%.

41. Material according to claim 35, wherein the filler gas (3) has a gas pressure of 0.5 mbar to 10 mbar, preferably from 0.5 mbar to 5 mbar and particularly preferably from 1 mbar to 3 mbar.

42. Material according to claim 35, wherein the gas discharge is generated by two electrodes (2) situated in the tube (4) and controlled by a ballast (5) connected to the electrodes (2).

43. Material according to claim 42, wherein a control of the power supply of the electrodes (2) the ballast (5) regulates the discharge tube temperature to about 85° C. to 150° C.

44. Material according to claim 35, wherein the gas discharge is generated electrode-free by high-energy radiation, in particular radiation in the microwave range.

45. Material according to claim 35, wherein the gas discharge lamp (1) is a medium pressure radiator.

46. Method according to claim 35, wherein the inert gas is a chemically inert gaseous compound, selected from the group consisting of argon, nitrogen or carbon dioxide.
